(19) United States
(12) Patent Application Publication
(10) Pub. No.: US 2016/0320696 A1
(43) Pub. Date: Nov. 3, 2016

(54) TEMPLATE SUBSTRATE, TEMPLATE SUBSTRATE MANUFACTURING METHOD, AND PATTERN FORMING METHOD

(71) Applicant: Kabushiki Kaisha Toshiba, Minato-ku (JP)

(72) Inventors: Takahito NISHIMURA, Kuwana (JP); Suigen KYOH, Nagoya (JP); Kazuhiro TAKAHATA, Kuwana (JP)

(73) Assignee: Kabushiki Kaisha Toshiba, Minato-ku (JP)

(21) Appl. No.: 14/834,617

(22) Filed: Aug. 25, 2015

(30) Foreign Application Priority Data
Apr. 28, 2015 (JP) 2015-092349

(51) Int. Cl. G03F 7/00; B29C 33/38

(52) U.S. Cl. CPC G03F 7/0002; B29C 33/3842

(57) ABSTRACT

According to an embodiment, a template substrate is provided. The template substrate is formed by a board-shaped member. The template substrate includes topography that is non-planar deviation in a predetermined region on a pattern surface of the board-shaped member on which a template pattern is formed.

### CROSS-REFERENCE TO RELATED APPLICATIONS

This application is based upon and claims the benefit of priority from Japanese Patent Application No. 2015-092349, filed on Apr. 28, 2015; the entire contents of which are incorporated herein by reference.

### FIELD

An embodiment of the present invention relates to a template substrate, a template substrate manufacturing method, and a pattern forming method.

### BACKGROUND

Nanoimprint technologies are used to transfer a template pattern formed on the surface of a template to a resist (imprint material) on a substrate. The resist is, for example, phot-curable resist.

In nanoimprint lithography, a template is pressed to a resist on a substrate so as to fill the template pattern with the resist. Subsequently, the filled resist is cured, and the template is separated from the substrate. This forms a concavo-convex (recess-protrusion) pattern on the resist on the substrate.

However, when the substrate has a large unevenness (topography), the followability of the template deteriorates near the unevenness. This causes a defective pattern. When the topography is large, a difference in thickness of the resist between the template and the substrate (referred to as RLT) is generated, and this increases the shearing force of the template. Thus, the difference in the RLT affects the Die-by-Die alignment. As a result, the accuracy of superposition of the substrate and the imprint pattern deteriorates.

To planarize the unevenness on a substrate, planarization techniques such as film forming, etch-back, and CMP are proposed. However, the techniques are insufficient for the unevenness on a nanoscale substrate.

### BRIEF DESCRIPTION OF THE DRAWINGS

FIGS. 1A and 1B are diagrams of the structures of template substrates according to an embodiment;

FIGS. 2A to 2D are explanatory diagrams of a process for manufacturing replica template substrates with a wafer;

FIGS. 3A to 3D are explanatory diagrams of a process for manufacturing master template substrates with the replica template substrate;

FIGS. 4A to 4D are explanatory diagrams of a process for manufacturing replica template substrates with the master template substrate;

FIGS. 5A to 5C are explanatory diagrams of a process for forming a pattern on a wafer with the replica template substrate; and

FIG. 6 is an explanatory diagram of the relationship among the concavo-convex patterns of the wafers, the replica template substrates, and the master template substrate.

### DETAILED DESCRIPTION

An embodiment provides a template substrate. The template substrate is formed by a board-shaped member. The template substrate includes topography that is non-planar deviation in a predetermined region on a pattern surface of the board-shaped member on which a template pattern is formed.

Exemplary embodiments of a template substrate, a template substrate manufacturing method, and a pattern forming method will be explained below in detail with reference to the accompanying drawings. The present invention is not limited to the following embodiments.

### Embodiment

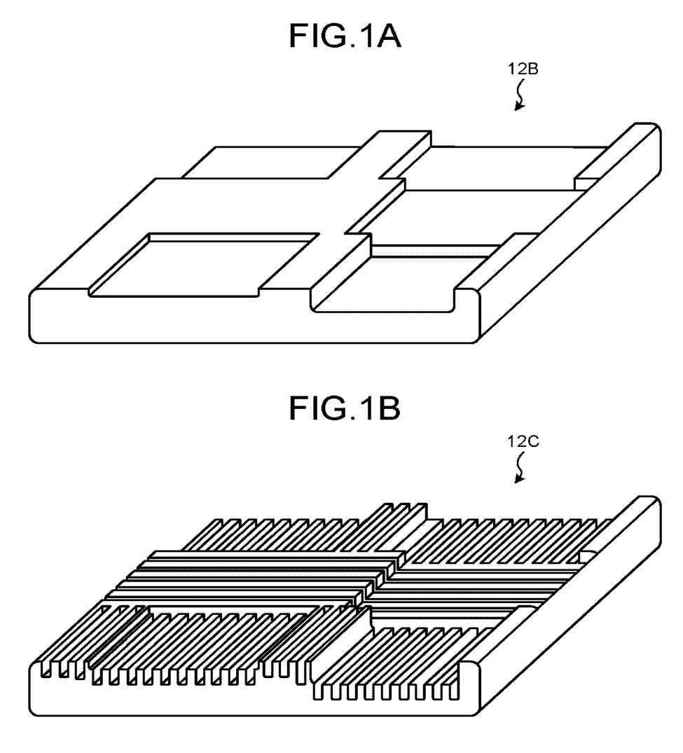

FIGS. 1A and 1B are diagrams of the structures of template substrates according to an embodiment. FIG. 1A illustrates a replica template substrate 12B, and FIG. 1B illustrates a replica template substrate 12C.

The replica template substrate 12B is an original plate (mask blanks) before a template pattern is formed thereon. The replica template substrate 12C is a template after the template pattern is formed thereon.

According to the present embodiment, the replica template substrate that is a first-generation substrate is formed with a wafer. The master template substrate that is a second-generation substrate is formed with the first-generation replica template substrate. The replica template substrate (child template substrate) that is a third-generation substrate is formed with the second-generation master template substrate (parent template substrate). For convenience of description, both of the first-generation substrate and the third-generation substrate are referred to as the replica template substrate in the present embodiment because both of them are the same substrate. The replica template substrate and the master template substrate are also referred to as a mold, a stamper, or a die and used for imprint lithography.

The replica template substrates 12B and 12C are the first-generation replica template substrates. The replica template substrate 12B is formed by a board-shaped member such as a silica glass substrate. The replica template substrate 12C is formed by the replica template substrate 12B. The replica template substrate 12C is an imprint mask used for imprint lithography such as nanoimprint lithography (NIL). The wafer is a substrate (a substrate to be printed) such as a semiconductor wafer. A semiconductor device is formed on the wafer, for example, by imprint lithography.

The replica template substrate 12B according to the present embodiment includes topography indicating the in-plane flatness on a surface on which a template pattern is formed (a first principal surface). The topography is the asperity having spatial frequency components of about 0.2 mm to 20 mm on the surface of the wafer, and is the non-planar deviation in a Fixed Quality Area (FQA). The topography includes a dip, a bump, and a wave on the surface of the wafer. The peaks of depths of the dip, bump, and wave vary between several and several hundred nanometers. The topography according to the present embodiment is the non-planar deviation in a predetermined region of spatial frequencies and in FQA in a predetermined area (for example, in a shot).

The wafer on which a semiconductor device is formed includes various types of topography on each process (layer). Thus, the topography appropriate to the layer of the wafer is formed on the replica template substrate 12B.

For example, there is a case in which a wafer is processed by an imprint process with the replica template substrate 12C in an Mth (M is a natural number) process. In such a case, the wafer processed in the Mth process includes first topography. If the replica template substrate 12C includes second topography opposite to the first topography (reversed the first topography) in the Mth process, the imprint process appropriate to the topography of the wafer can be performed.

Thus, the second topography appropriate to the first topography is formed on the replica template substrate 12B in the present embodiment. The second topography is opposite to the first topography. The topography on the replica template substrate 12B is formed by an imprint process in which the wafer is pressed to a resist on a glass substrate (a replica template substrate 12A described below).

As illustrated in FIG. 1B, the replica template substrate 12C is the replica template substrate 12B on which the template pattern is formed. The replica template substrate 12C is formed from the replica template substrate 12B. Thus, the replica template substrate 12C includes the same topography as that of the replica template substrate 12B.

The topography formed on the replica template substrate 12C is the topography in a shot. Note that template patterns for a plurality of shots may be formed on the replica template substrate 12C. The template pattern is a finely concavo-convex pattern and is, for example, a circuit pattern (a device pattern).

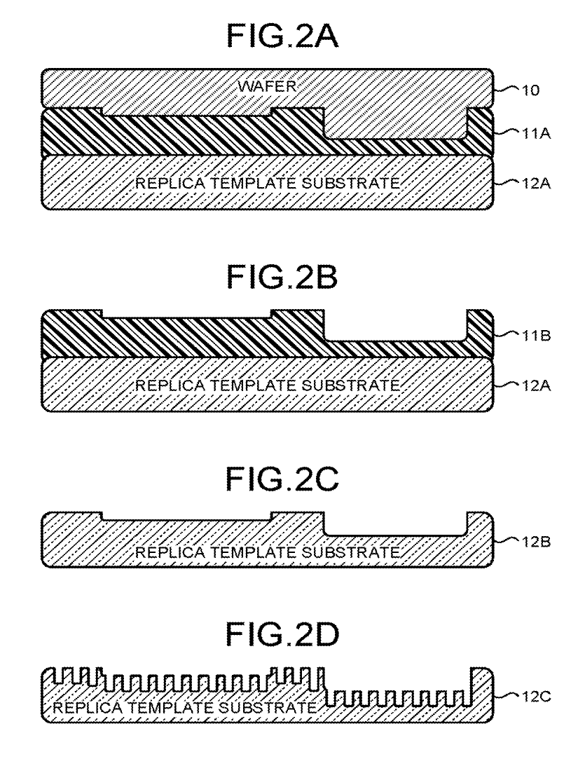

FIGS. 2A to 2D are explanatory diagrams of a process for manufacturing the replica template substrates with a wafer. A resist 11A is dropped on the replica template substrate 12A. The replica template substrate 12A is, for example, an approximately flat board-shaped glass substrate, and does not include topography. Meanwhile, the replica template substrate 12A is the substrate on which the topography of a wafer 10 is to reversely be transferred, and which is used as a replica template substrate. The topography is formed on the first surface of the wafer 10 (the pattern-formed surface). Meanwhile, the wafer 10 is used as an original plate to reversely transfer the topography.

After the dropping of the resist 11A, the topography-formed surface of the wafer 10 is pressed to the resist 11A on the replica template substrate 12A as illustrated in FIG. 2A. Specifically, the wafer 10 or the replica template substrate 12A is moved so as to maintain a predetermined distance between the wafer 10 and the replica template substrate 12A. A plurality of shots is placed on the wafer 10. The wafer 10 includes nearly the same topography on each of the shots. Thus, any of the shots on the wafer 10 is pressed to the resist 11A.

The wafer 10 has contact with the resist 11A for a predetermined period of time. Subsequently, for example, a UV light is emitted from below the bottom of the replica template substrate 12A (the surface opposite to the surface on which the pattern is to be formed) while the contact is maintained. This irradiation cures (hardens) the resist 11A and patterns a transfer pattern appropriate to the topography of the wafer 10 on the resist 11A.

Subsequently, the wafer 10 is separated from the cured resist 11A. This forms a resist pattern 11B opposite to the topography of the wafer 10 on the replica template substrate 12A as illustrated in FIG. 2B.

After that, the surface of the replica template substrate 12A is entirely etched from above the resist pattern 11B by etch-back. This etching back forms the replica template substrate 12B including the same topography as that of the resist pattern 11B as illustrated in FIG. 2C. Forming a template pattern on the replica template substrate 12B forms the replica template substrate 12C as illustrated in FIG. 2D.

To form the replica template substrate 12C, for example, a resist is applied to the replica template substrate 12B and a resist pattern is formed with an electron-beam writer. The replica template substrate 12B is etched, using the resist pattern as a mask. This etching forms the replica template substrate 12C. In the present embodiment, the replica template substrates 12B and 12C are the first-generation substrates.

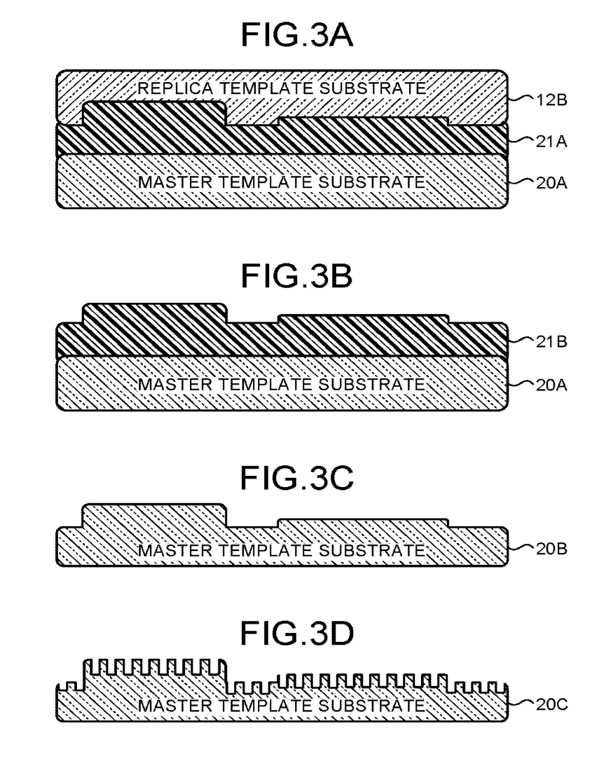

Next, a process for manufacturing a second-generation master template substrate with the first-generation replica template substrate 12B will be described. FIGS. 3A to 3D are explanatory diagrams of a process for manufacturing the master template substrates with the replica template substrate. A resist 21A is dropped on a master template substrate 20A. The master template substrate 20A is, for example, an approximately flat board-shaped glass substrate, and does not include topography.

After the dropping of the resist 21A, the topography-formed surface of the replica template substrate 12B is pressed to the resist 21A on the master template substrate 20A as illustrated in FIG. 3A. Specifically, the replica template substrate 12B or the master template substrate 20A is moved so as to maintain a predetermined distance between the replica template substrate 12B and the master template substrate 20A.

The replica template substrate 12B has contact with the resist 21A for a predetermined period of time. Subsequently, for example, a UV light is emitted from above the replica template substrate 12B or below the bottom of the master template substrate 20A while the contact is maintained. This irradiation cures the resist 21A and patterns a transfer pattern appropriate to the topography of the replica template substrate 12B on the resist 21A.

Subsequently, the replica template substrate 12B is separated from the cured resist 21A. This forms a resist pattern 21B opposite to the topography of the replica template substrate 12B on the master template substrate 20A as illustrated in FIG. 3B.

After that, the surface of the master template substrate 20A is entirely etched from above the resist pattern 21B by etch-back. This etching back forms a master template substrate 20B including the same topography as that of the resist pattern 21B as illustrated in FIG. 3C. Forming a template pattern on the master template substrate 20B forms a master template substrate 20C as illustrated in FIG. 3D. In the present embodiment, the master template substrates 20B and 20C are the second-generation substrates.

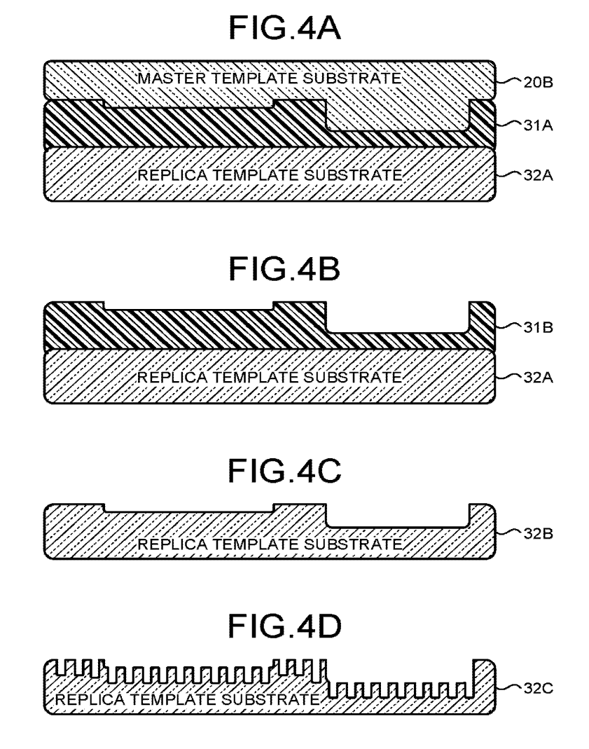

Next, a process for manufacturing a third-generation replica template substrate with the second-generation master template substrate 20B will be described. FIGS. 4A to 4D are explanatory diagrams of a process for manufacturing the replica template substrates with the master template substrate. A resist 31A is dropped on a replica template substrate 32A. The replica template substrate 32A is, for example, an approximately flat board-shaped glass substrate, and does not include topography.

After the dropping of the resist 31A, the topography-formed surface of the master template substrate 20B is pressed to the resist 31A on the replica template substrate 32A as illustrated in FIG. 4A. Specifically, the master template substrate 20B or the replica template substrate 32A is moved so as to maintain a predetermined distance between the master template substrate 20B and the replica template substrate 32A.

The master template substrate 20B has contact with the resist 31A for a predetermined period of time. Subsequently, for example, a UV light is emitted from above the master template substrate 20B or below the bottom of the replica template substrate 32A while the contact is maintained. This irradiation cures the resist 31A and patterns a transfer pattern appropriate to the topography of the master template substrate 20B on the resist 31A.

Subsequently, the master template substrate 20B is separated from the cured resist 31A. This forms a resist pattern 31B opposite to the topography of the master template substrate 20B on the replica template substrate 32A as illustrated in FIG. 4B.

After that, the surface of the replica template substrate 32A is entirely etched from above the resist pattern 31B by etch-back. This etching back forms a replica template substrate 32B including the same topography as that of the resist pattern 31B as illustrated in FIG. 4C. Forming a template pattern on the replica template substrate 32B forms a replica template substrate 32C as illustrated in FIG. 4D. In the present embodiment, the replica template substrates 32B and 32C are the third-generation substrates.

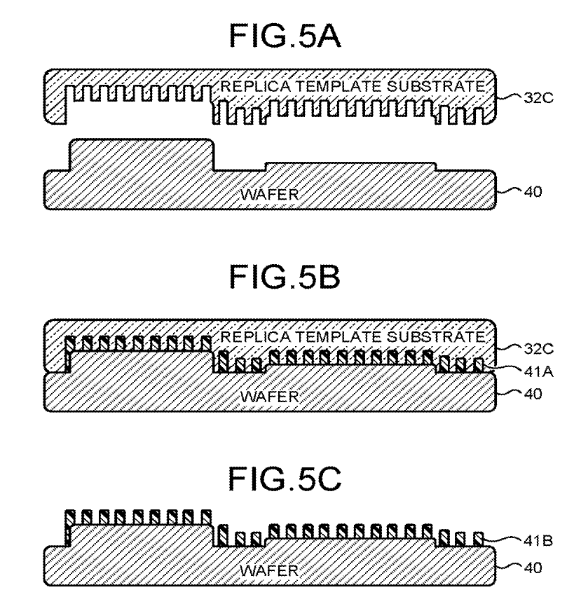

Next, a process for forming a pattern on a wafer with the third-generation replica template substrate 32C will be described. FIGS. 5A to 5C are explanatory diagrams of a process for forming a pattern on the wafer with the replica template substrate.

As illustrated in FIG. 5A, a wafer 40 having the same structure as the wafer 10 and the replica template substrate 32C are prepared. The same film as the film on the wafer 10 is stacked on the wafer 40, and thus the wafer 40 and the wafer 10 include the same topography. Note that the wafer 10 may be used instead of the wafer 40. Also, the replica template substrate 12C may be used instead of the replica template substrate 32C.

A resist 41A is dropped on the wafer 40 including the topography. After the dropping of the resist 41A, the replica template substrate 32C is pressed to the resist 41A on the wafer 40 as illustrated in FIG. 5B. Specifically, the replica template substrate 32C or the wafer 40 is moved so as to maintain a predetermined distance between the replica template substrate 32C and the wafer 40.

The replica template substrate 32C has contact with the resist 41A for a predetermined period of time. Subsequently, the resist 41A is irradiated, for example, with a UV light from below the bottom of the replica template substrate 32C while the contact is maintained. This irradiation cures the resist 41A and patterns a transfer pattern appropriate to the topography and template pattern of the replica template substrate 32C on the resist 41A.

Subsequently, the replica template substrate 32C is separated from the cured resist 41A. This forms an on-wafer pattern (a resist pattern 41B) on the wafer 40 having the topography as illustrated in FIG. 5C.

In the present embodiment, the topography appropriate to the topography of the wafers 10 and 40 is formed on the replica template substrate 32C. In other words, the wafers 10 and 40 have the topography opposite to the topography of the replica template substrate 32C.

The wafer 40 is processed by the imprint lithography with the replica template substrate 32C. This can achieve a patterning with a high degree of accuracy even on the unevenness of a nanoscale wafer 40.

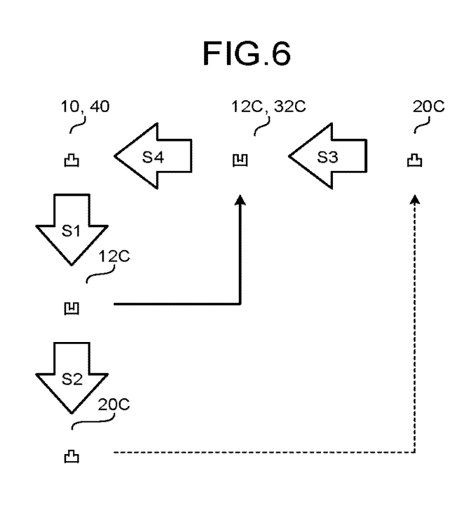

The relationship among the concavo-convex patterns of the wafers 10 and 40, the replica template substrates 12C and 32C, and the master template substrate 20C will be described. FIG. 6 is an explanatory diagram of the relationship among the concavo-convex patterns of the wafers, the replica template substrates, and the master template substrate.

The replica template substrate 12C is formed by the imprint lithography with the wafer 10 (S1). Subsequently, the master template substrate 20C is formed by the imprint lithography with the replica template substrate 12C (S2).

The concavo-convex pattern is reversed in the imprint lithography. Specifically, the concavo-convex pattern of a template substrate to be pressed to a resist and the concavo-convex pattern of a resist pattern to be formed are opposite to each other. In other words, the asperity of the topography is reversed in the imprint lithography.

Thus, if the pattern (the concavo-convex pattern) on the wafer 10 is convex (recess), a concave (protrusion) pattern is formed on the replica template substrate 12C. Furthermore, if a concave pattern is formed on the replica template substrate 12C, a convex pattern is formed on the master template substrate 20C. In other words, the topography of the convex pattern on the wafer 10 is transferred as the topography of a concave pattern to the replica template substrate 12C. Furthermore, the topography of the concave pattern on the replica template substrate 12C is transferred as the topography of a concave pattern to the master template substrate 20C.

The master template substrate 20C is formed, and subsequently the replica template substrate 32C is formed by the imprint lithography with the master template substrate 20C (S3). Thus, if a convex pattern is formed on the master template substrate 20C, a concave pattern is formed on the replica template substrate 32C. In other words, the topography of the convex pattern on the master template substrate 20C is transferred as the topography of a concave pattern to the replica template substrate 32C.

An on-wafer pattern is formed on the wafer 40 by the imprint lithography with one of the replica template substrates 12C and 32C (S4). Thus, if the replica template substrates 12C and 32C are concave patterns, the on-wafer pattern formed on the wafer 40 is a convex pattern. In other words, the topography of the convex patterns on the replica template substrates 12C and 32C is transferred as the topography of a concave pattern to the wafer 40.

As described above, the concave pattern in the topography on the replica template substrates 12C and 32C is pressed to the convex pattern in the topography on the wafer 40. The convex pattern in the topography on the replica template substrates 12C and 32C is pressed to the concave pattern in the topography on the wafer 40.

The wafer 10 includes various types of topography in each process. Thus, the replica template substrates 12C and 32C and the master template substrate 20C are manufactured in each process. For example, the replica template substrates 12C and 32C and the master template substrate 20C are manufactured for the wafer 10 on which the first layer is formed. Similarly, the replica template substrates 12C and 32C and the master template substrate 20C are manufactured for the wafer 10 on which an Nth (N is a natural number) layer is formed.

An on-wafer pattern is formed on the wafer 40 on which the first layer is formed, using the replica template substrate 32C appropriate to the first layer. Similarly, an on-wafer pattern is formed on the wafer 40 on which an Nth layer, using the replica template substrate 32C appropriate to the Nth layer.

For each layer in the wafer process, the replica template substrates 12C and 32C and the master template substrate 20C are manufactured and then a resist pattern is formed with the replica template substrate 32C as described above.

To form a semiconductor device on the wafer 40, the resist 41A is applied on the wafer 40. Subsequently, the resist pattern is formed with the replica template substrate 32C. After that, the lower layer of the resist pattern is etched, using the resist pattern as a mask. This forms an actual pattern corresponding to the resist pattern is formed on the wafer 40. To manufacture a semiconductor device, for example, the process for manufacturing the replica template substrates 12C and 32C, and the master template substrate 20C, the etching process, and the process for forming a film are repeated on each layer. Note that the imprint lithography with the replica template substrate 32C is not required on every layer in order to manufacture a semiconductor device. Another lithography technique or the like may be used.

The resist 11A is dropped on the replica template substrate 12A in the description with reference to FIGS. 2A to 2D. Note that, however, the resist 11A may be dropped on the wafer 10. The resist 21A is dropped on the master template substrate 20A in the description with reference to FIGS. 3A to 3D. Note that, however, the resist 21A may be dropped on the replica template substrate 12B. The resist 31A is dropped on the replica template substrate 32A in the description with reference to FIGS. 4A to 4D. Note that, however, the resist 31A may be dropped on the master template substrate 20B.

The wafer 10 is separated from the resist 11A in the description with reference to FIGS. 2A to 2D. Note that, however, the resist 11A and the replica template substrate 12A may be separated from the wafer 10. The resist 11A remains on the replica template substrate 12A even if the resist 11A and the replica template substrate 12A are separated from the wafer 10 in such a manner. Thus, the adhesion between the resist 11A and the replica template substrate 12A is made higher than that between the resist 11A and the wafer 10.

The replica template substrate 12B is separated from the resist 21A in the description with reference to FIGS. 3A to 3D. Note that, however, the resist 21A and the master template substrate 20A may be separated from the replica template substrate 12B. The resist 21A remains on the master template substrate 20A even if the resist 21A and the master template substrate 20A are separated from the replica template substrate 12B in such a manner. Thus, the adhesion between the resist 21A and the master template substrate 20A is made higher than that between the resist 21A and the replica template substrate 12B.

The master template substrate 20B is separated from the resist 31A in the description with reference to FIGS. 4A to 4D. Note that, however, the resist 31A and the replica template substrate 32A may be separated from the master template substrate 20B. The resist 31A remains on the replica template substrate 32A even if the resist 31A and the replica template substrate 32A are separated from the master template substrate 20B in such a manner. Thus, the adhesion between the resist 31A and the replica template substrate 32A is made higher than that between the resist 31A and the master template substrate 20B.

In the present embodiment, the topography of the wafer 10 is reversely transferred to the replica template substrate 12A. However, the topography of another substrate other than the wafer 10 may reversely be transferred to the replica template substrate 12A. In such a case, the pattern is reversely transferred to a substrate having the same topography as that of the substrate other than the wafer 10 by the imprint lithography with the replica template substrates 12C and 32C.

According to the embodiment described above, each of the replica template substrates 12B, 12C, 32B, and 32C includes the topography that is the non-planar deviation in a predetermined region on the surface on which a template pattern is to be formed. The topography is opposite to the topography of the wafers 10 and 40. Thus, the imprint lithography on the wafer 40 with the replica template substrates 12B, 12C, 32B, and 32C can form a highly accurate pattern that is hardly affected by the unevenness (topography) of the wafer 40.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template substrate comprising:
topography on a pattern surface of a board-shaped member on which a template pattern is formed, the topography being non-planar deviation in a predetermined region,
the template substrate being formed by the board-shaped member.

2. The template substrate according to claim 1,
wherein the template pattern is formed in a region in which the topography is provided on the pattern surface.

3. The template substrate according to claim 2,
wherein the template pattern is formed as a pattern larger than a pattern of the topography.

4. The template substrate according to claim 1,
wherein the pattern of the topography is asperity having spatial frequency components of 0.2 to 20 mm and existing on a surface of a wafer.

5. The template substrate according to claim 1,
wherein the topography is formed by pressing a wafer to a resist placed on the board-shaped member.

6. The template substrate according to claim 1,
wherein the topography is formed by imprint lithography.

7. The template substrate according to claim 1,
wherein the template pattern is formed by imprint lithography.

8. A template substrate manufacturing method, the method comprising:
maintaining a predetermined distance between a substrate including first topography and a first template substrate on which a resist is placed, the first topography being non-planar deviation in a predetermined region;
curing the resist;
separating the substrate from the resist;
performing etch-back from above the resist; and
forming second topography on the first template substrate, the second topography being opposite to the first topography.

9. The template substrate manufacturing method according to claim 8, the method comprising:
forming a template pattern on the first template substrate after the forming of the second topography.

10. The template substrate manufacturing method according to claim 8,
wherein the substrate is a wafer.

11. The template substrate manufacturing method according to claim 9,
wherein the template pattern is formed by imprint lithography.

12. The template substrate manufacturing method according to claim 9,
wherein the template pattern is formed with an electron-beam writer.

13. A pattern forming method, the method comprising:
forming second topography on a first template substrate with a first substrate including first topography, the second topography being opposite to the first topography, the first topography being non-planar deviation in a predetermined region;
forming a template pattern on the first template substrate;
processing a second substrate including topography identical to the first topography by imprint lithography with the first template substrate; and
forming the template pattern and a pattern opposite to the second topography on the second substrate.

14. The pattern forming method according to claim 13,
wherein the first template substrate is formed by imprint lithography with the first substrate.

15. The pattern forming method according to claim 13,
wherein the first substrate is a wafer.

16. The pattern forming method according to claim 13,
wherein the second substrate is a wafer.

17. The pattern forming method according to claim 13,
wherein the template pattern is formed by imprint lithography.

18. The pattern forming method according to claim 13,
wherein the template pattern is formed with an electron-beam writer.

19. The pattern forming method according to claim 13, the method further comprising:
forming the first topography on a third template substrate by imprint lithography with a second template substrate including the second topography, the first topography being opposite to the second topography; and
forming the second topography on the first template substrate by imprint lithography with the third template substrate, the second topography being opposite to the first topography.

20. The pattern forming method according to claim 19,
wherein the second template substrate is formed by imprint lithography with the first substrate.
